(19) United States
(12) Patent Application Publication
(10) Pub. No.: US 2010/0038658 A1
(43) Pub. Date: Feb. 18, 2010

(54) Polymer light-emitting diode and fabrication of same by resonant infrared laser vapor deposition

(75) Inventors: Richard F. Haglund, JR., Brentwood, TN (US); Stephen L. Johnson, Nashville, TN (US); Hee K. Park, San Jose, CA (US)

Correspondence Address: MORRIS MANNING MARTIN LLP, 3343 PEACHTREE ROAD, NE, 1600 ATLANTA FINANCIAL CENTER, ATLANTA, GA, 30326, US

(73) Assignee: Vanderbilt University, Nashville, TN (US)

(21) Appl. No.: 11/899,879

(22) Filed: Sep. 7, 2007

Related U.S. Application Data
(60) Provisional application No. 60/843,717, filed on Sep. 11, 2006.

(51) Int. Cl. H01L 33/00; H01L 21/30; B05D 3/00

(52) U.S. Cl. 257/98; 438/29; 427/561; 257/E21.211; 257/E33.061

(57) ABSTRACT

A polymeric light-emitting diode (PLED) and methods of making same. In one embodiment, the PLED comprises a substrate, a layer of a first conductive material formed on a surface of the substrate, a layer of a conductive polymeric material deposited on the layer of the first conductive material, a layer of a luminescent polymeric material deposited on the layer of the conductive polymeric material, and a layer of a second conductive material formed on the layer of the luminescent polymeric material, wherein at least one of the layer of the conductive polymeric material and the layer of the luminescent polymeric material is deposited by the laser vapor deposition (LVD).

### CROSS-REFERENCE TO RELATED PATENT APPLICATION

This application claims the benefit, pursuant to 35 U.S.C. §119(e), of U.S. provisional patent application Ser. No. 60/843,717, filed Sep. 11, 2006, entitled “POLYMER LIGHT-EMITTING DIODE AND FABRICATION OF SAME BY RESONANT INFRARED LASER VAPOR DEPOSITION,” by Richard F. Haglund, Jr., Stephen L. Johnson and Hee K. Park, which is incorporated herein by reference in its entirety.

This application is related to a co-pending U.S. patent application Ser. No. 11/444,165 (“the application '165”), filed May 31, 2006, entitled “SOLVENT-ENHANCED WAVELENGTH-SELECTIVE INFRARED LASER VAPOR DEPOSITION OF POLYMERS AND APPLICATIONS OF SAME,” by Hee K. Park, Stephen L. Johnson and Richard F. Haglund, Jr., the content of which is incorporated herein in its entirety by reference.

The application '165 is also related to a co-pending U.S. patent application Ser. No. 11/337,301, (“the application '301”) filed Jan. 23, 2006, entitled “METHODS AND APPARATUS FOR TRANSFERRING A MATERIAL ONTO A SUBSTRATE USING A RESONANT INFRARED PULSED LASER,” by Richard F. Haglund, Jr., Nicole L. Dygert, and Kenneth E. Schriver. The application '301 is a continuation-in-part of U.S. patent application Ser. No. 10/059,978, filed Jan. 29, 2002, now issued as U.S. Pat. No. 6,998,156, entitled “DEPOSITION OF THIN FILMS USING AN INFRARED LASER,” by Daniel Bubb, James Horwitz, John Callahan, Richard Haglund, Jr. and Michael Papantonakis, and also claims the benefit, pursuant to 35 U.S.C. §119(e), of U.S. provisional patent application Ser. No. 60/714,819, filed Sep. 7, 2005, entitled “A RESONANT INFRARED PULSED LASER SYSTEM FOR TRANSFERRING A MATERIAL ONTO A SUBSTRATE AND APPLICATIONS OF SAME,” by Richard F. Haglund, Jr., Nicole L. Dygert, and Kenneth E. Schriver, the contents of which are incorporated herein in their entireties by reference, respectively.

Some references, which may include patents, patent applications and various publications, are cited and discussed in the description of this invention. The citation and/or discussion of such references is provided merely to clarify the description of the present invention and is not an admission that any such reference is “prior art” to the invention described herein. All references cited and discussed in this specification are incorporated herein by reference in their entireties and to the same extent as if each reference was individually incorporated by reference. In terms of notation, hereinafter, “[n]” represents the nth reference cited in the reference list. For example, [8] represents the 8th reference cited in the reference list, namely, “UV and RIR matrix-assisted pulsed laser deposition of MEH-PPV films,” B. Toftmann, M. R. Papantonakis, R. C. Y. Auyeung, W. Kim, S. M. O'Malley, D. M. Bubb, J. S. Horwitz, J. Schou, P. M. Johansen and R. F. Haglund, Jr., Thin Solid Films 453-454, 177-181 (2004).

### STATEMENT OF FEDERALLY-SPONSORED RESEARCH

The present invention was made with Government support awarded by the Department of Defense Medical Free-Electron Laser Program under Grant No. F49620-01-1-0429. The United States Government may have certain rights to this invention pursuant to this grant.

### FIELD OF THE INVENTION

The present invention generally relates to laser vapor deposition (LVD), and in particular to methods and apparatus of forming polymer light-emitting diodes (PLEDs) by resonant infrared laser vapor deposition of one or more polymeric materials, which utilizes one or more solvents and selective laser excitation of a vibrational mode of the one or more solvents.

### BACKGROUND OF THE INVENTION

Infrared pulsed laser deposition (PLD) was first reported in 1960's but did not emerge as a thin film coating technology at that time for a number of reasons. These include the slow repetition rate of the available lasers, and the lack of commercially available high power lasers. At that time, infrared PLD used infrared laser light of 1.06 μm that was not resonant with any single photon absorption band of the material being deposited. Although PLD developed through the years it was not until late 1980's that ultraviolet PLD became popular with the discovery of complex superconducting ceramics and the commercial availability of high energy, high repetition rate lasers. Ultraviolet PLD is now a common laboratory technique used for the production of a broad range of thin film materials.

Ultraviolet PLD has been an extremely successful technique for the deposition of thin films of a large variety of complex, multi-component inorganic materials. Ultraviolet PLD has also been applied to the growth of thin polymeric and organic films, with varying degrees of success. It has been shown that polymethyl methacrylate, polytetrafluoroethylene and polyalphamethyl styrene undergo rapid depolymerization during ultraviolet laser ablation, with the monomer of each strongly present in the ablation plume. The photochemical modification occurs because the energy of the ultraviolet laser causes the irradiated material to be electronically excited. The geometry of the excited electronic state can be very different from the ground electronic state. Relaxation of the excited state can be to either the ground state of the starting material, or the ground state of a geometrically different material. Deposited films are therefore photochemically modified from the starting material, showing a dramatic reduction in the number average molecular weight. For these polymers, depositing the film at an elevated substrate temperature can increase the molecular weight distribution of the deposited thin film material. On arrival, monomeric material repolymerizes on the heated substrate surface, with degree of repolymerization being determined by the thermal activity of the surface. Therefore, even in some of the most successful cases of ultraviolet PLD, the intense interaction between the target material and laser leads to chemical modification of the polymer.

An alternative approach to PLD of polymeric materials with ultraviolet lasers is matrix-assisted pulsed laser evaporation (MAPLE), disclosed in U.S. Pat. No. 6,025,036 and other references, where roughly 0.1-1% of a polymer material to be deposited is dissolved in an appropriate solvent and frozen to form an ablation target. The ultraviolet laser light interacts mostly with the solvent and the guest material is evaporated much more gently than in conventional PLD. While this technique can produce smooth and uniform polymer films, it requires that the polymer of interest be soluble in a non-interacting solvent. Finding a suitable solvent system that is also non-photochemically active is a significant challenge and limits the usefulness of the technique. There are examples where electronic excitation of the solvent/polymer system has been observed to produce undesirable photochemical modification of the polymer, such as reduction in the average weight average molecular weight. An additional disadvantage of the matrix-assisted pulsed laser evaporation is that the deposition rate is about an order of magnitude lower than conventional PLD, which can render matrix-assisted pulsed laser evaporation ineffective for applications that require thick, i.e., greater than about 1 μm, coatings.

Recent reports show that it is possible to transfer a number of organic and polymeric materials from a bulk sample into a thin film by the way of infrared laser vapor deposition (IR-LVD) from a target [4] containing the material to be deposited in a suitable carrier. Infrared laser radiation, tuned to a weak vibrational resonance of the target, is then focused onto the target under vacuum. The incident radiation is absorbed by the matrix, generating a plume of ablated material that subsequently condenses onto a nearby substrate. IR-LVD differs from the MAPLE process using ultraviolet excimer lasers in two fundamental ways: (1) it does not rely on the use of a strong electronic excitation to initiate the phase change and vaporization of the matrix, and hence does not require the use of volatile organic matrix material; and (2) the IR-LVD process does not produce significant electronic excitation because vaporization is induced by vibrational excitation. Thus, IR-LVD avoids the principal vaporization mechanisms capable of inducing photochemical damage to the target material. Also, because of the greater penetration depth of the IR laser in the matrix material, vaporization and deposition rates are substantially higher than those characteristic of UV-MAPLE.

The ability to deposit polymeric materials in the form of a thin film is important for a wide range of uses including electronics, chemical sensors, photonics, analytical chemistry and biological sciences and technologies. An important biomedical application of polymer thin films is for biocompatible polymer thin films on drug particles. The coating serves to both delay and regulate the release of the drug in the body. Two techniques that have been demonstrated in the coating of drug particles include wet chemical technique and a vapor deposition technique. In the wet chemical technique, the coated particle can be more than 50% coating on weight bases. A coating that minimizes the coating to drug weight ratio is desired for obvious reasons. It is also important to control the thickness of the deposited film since control of the dissolution rate governs the rate of drug delivery. While UV-PLD has been used to deposit much thinner (on the order of a few hundred Å) coatings on drug particles, the deposition process introduces significant and undesirable chemical modification in the coating material as a consequence of the ultraviolet excitation.

All these and other known methods suffer from the same difficulties with regard to film uniformity as those listed above for dip coating and spin coating. They share all the disadvantages of solvent-based techniques insofar as solvent compatibility is concerned. Moreover, they are serial processing techniques and therefore the production throughput drops rapidly with increasing substrate size. Therefore, a heretofore unaddressed need still exists in the art to address the aforementioned deficiencies and inadequacies.

### SUMMARY OF THE INVENTION

Among other unique features, the present invention provides, for the first time, a polymeric light-emitting diode (PLED) and methods of making same by laser vapor deposition (LVD). More specifically, the present invention, in one aspect, relates to a method for making a PLED. In one embodiment, the method includes the steps of: providing a solution having at least one polymeric material and one or more solvents, where at least one solvent has a vibrational mode; freezing the solution to form a target; directing a light of a wavelength in the infrared region which is resonant with the vibrational mode at the target to vaporize the at least one polymeric material in the target without decomposing the at least one polymeric material; depositing the vaporized at least one polymeric material on a substrate to form a layer of the polymeric material; and forming a cathode component on the layer of the polymeric material so as to form a PLED.

The cathode component comprises a metallic or liquid-metal cathode. In one embodiment, the liquid-metal cathode is an indium-alloy liquid-metal cathode. The metal cathode is an aluminum cathode, a copper cathode, a silver cathode, a gold cathode or the like. The substrate is a transparent conducting substrate. In one embodiment, the substrate is an indium-tin oxide coated glass substrate, where a layer of the indium-tin oxide is deposited on a surface of a glass substrate. The substrate is configured to have an anode component. When a voltage is applied between the anode component and the cathode component, a light is emitted from the PLED.

The at least one polymeric material is semi-conductive or conductive. In one embodiment, the at least one polymeric material includes a luminescent polymeric material. The luminescent polymeric material includes MEH-PPV, which is semi-conductive.

In another embodiment, the at least one polymeric material includes a hole-transport polymeric material. The hole-transport polymeric material can be Poly(3,4-ethylenedioxythiophene) (PEDOT) or Poly(3,4-ethylenedioxythiophene)-poly(styrenesulfonate) (PEDOT:PSS). Furthermore, the at least one polymeric material may also include a luminescent polymeric material, such as MEH-PPV. In this embodiment, the step of depositing the vaporized at least one polymeric material on the substrate to form a layer of the polymeric material comprises the steps of depositing the vaporized PEDOT or PEDOT:PSS on the indium-tin oxide coated glass substrate to form a layer of PEDOT or PEDOT:PSS; and depositing the vaporized luminescent polymeric material on the layer of PEDOT or PEDOT:PSS to form a layer of the luminescent polymeric material.

In one embodiment, the one or more solvents comprise a chemically stable solvent. The chemically stable solvent, in one embodiment, comprises water, where the light is resonant with a vibrational mode of water in liquid form or in solid form.

The one or more solvents may comprise an additional solvent that is at least partially soluble in the chemically stable solvent and has a vibrational mode that may be different from that of the chemically stable solvent. In one embodiment, the additional solvent comprises N-Methyl-2-pyrrolidinone having a vibrational mode of N-Methyl-2-pyrrolidinone about 3.45 microns, where the light is resonant with a vibrational mode of N-Methyl-2-pyrrolidinone. The additional solvent alternatively may comprise dichlorobenzene.

The chemically stable solvent has a concentration in the range of about 5% to 95% by volume in the solution, the additional solvent has a concentration in the range of about 1% to 90% by volume in the solution, and the semi-conductive or conductive polymeric material is in the range of about 0.1% to 90% by weight in the solution.

The light is resonant with one of the vibrational modes of the one or more solvents, where the vibrational mode is in the infrared region of 1 to 100 microns.

The method further comprises the steps of subjecting the target and the substrate to an environment selected from the group consisting of sub-atmospheric, atmospheric and above atmospheric pressure and locating the target and the substrate in the vicinity of each other so that the vaporized at least one polymeric material from the target is deposited on the substrate by a movement of the vaporized at least one polymeric material, wherein the temperature of the substrate is such that the vaporized at least one polymeric material deposited on the substrate becomes solid. The environment, in one embodiment, is sub-atmospheric pressure and the sub-atmospheric pressure is in the range of about 1×10^{31 0} Torr to 1×10⁻⁶ Torr. The distance between the target and the substrate is in the range of about 1 to 20 cm.

The thickness of the layer of the semi-conductive or conductive polymeric material deposited on the substrate is in the range of about 10 Å to 500 microns.

The light directing at the target is generated from a coherent light source. In one embodiment, the coherent light source includes an infrared laser. The infrared laser, in one embodiment, is capable of emitting pulses of coherent light with a flurency in a range of about 0.01 to 100 J/cm². The pulses of coherent light have a pulse duration in a range of about 100 fs to 5 ms at a pulse repetition frequency in a range of about 1 Hz to 3 GHz. The infrared laser is configured such that the pulses of coherent light are delivered in the form of a pulse train in a burst of a micropulse mode lasting microseconds to milliseconds. In one embodiment, the infrared laser is configured such that the pulses of coherent light are delivered in the form of a pulse train on a continuous basis. The infrared laser, in another embodiment, is capable of emitting coherent light of a continuous wave mode. The infrared laser can be a free electron laser, a CO₂ laser, a tunable Optical Parametric Oscillator (“OPO”) laser system, a tunable Optical Parametric Amplifier (“OPA”) laser system, an N₂ laser, an excimer laser, a Holmium-doped:Yttrium Aluminum Garnet (Ho:YAG) laser, or an Erbium doped: Yttrium Aluminum Garnet (“Er:YAG”) laser.

In operation, the infrared laser is operating in cooperation with a rotatable holder supporting the substrate such that the laser delivers a laser spot that rastered on the surface of the target in synchronization with a rotation of the rotatable holder.

In another aspect, the present invention relates to a method for forming a PLED. In one embodiment, the method includes the steps of (a) providing a first target in a frozen state and a second target in a frozen state, wherein the first target includes a conductive polymeric material and one or more first solvents, at least one first solvent having a vibrational mode, wherein the second target includes a luminescent polymeric material and one or more additional solvents, at least one additional solvent having a vibrational mode, and wherein the one or more additional solvents are identical to or substantially different from the one or more first solvents; (b) directing a first light at the first target to vaporize the conductive polymeric material in the first target without decomposing the conductive polymeric material, wherein the first light has a wavelength in the infrared region which is resonant with the vibrational mode of the first target; (c) depositing the vaporized conductive polymeric material on a substrate to form a layer of the conductive polymeric material; (d) repeating steps (b) and (c) for the second target to form a layer of the luminescent polymeric material on the layer of the conductive polymeric material, wherein a second light directing at the second target has a wavelength in the infrared region which is resonant with the vibrational mode of the second target so as to vaporize the luminescent polymeric material in the second target without decomposing the luminescent polymeric material; and (e) forming a cathode component on the layer of the luminescent polymeric material so as to form a PLED.

The conductive polymeric material comprises a hole-transport polymeric material. In one embodiment, the hole-transport polymeric material is PEDOT or PEDOT:PSS. The luminescent polymeric material includes MEH-PPV.

In one embodiment, the substrate is a transparent conducting substrate having a glass substrate coated with a layer of an indium-tin oxide (ITO) configured to have an anode component. When a voltage is applied between the anode component and the cathode component, a light is emitted from the PLED.

Each of the one or more first solvents and the one or more additional solvents includes a chemically stable solvent having a vibrational mode.

The first light and the second light are generated from a single light source such as an infrared laser, or two different light sources, for example, two infrared lasers.

In yet another aspect, the present invention relates to a PLED. In one embodiment, the PLED has a substrate, a layer of a first conductive material formed on a surface of the substrate, a layer of a conductive polymeric material deposited on the layer of the first conductive material, a layer of a luminescent polymeric material deposited on the layer of the conductive polymeric material, and a layer of a second conductive material formed on the layer of luminescent polymeric material, where at least one of the layer of a conductive polymeric material and the layer of a luminescent polymeric material is deposited by the LVD.

The substrate is at least partially transparent. In one embodiment, the transparent substrate is a glass substrate. The layer of a first conductive material is a layer of at least partially transparent conducting oxide that is configured to be an anode component. In one embodiment, the layer of at least partially transparent conducting oxide is a layer of indium tin oxide (ITO). The layer of a conductive polymeric material comprises a layer of a hole-transport polymeric material. In one embodiment, the hole-transport polymeric material is PEDOT or PEDOT:PSS. The layer of a luminescent polymeric material comprises a semi-conductive polymeric material. In one embodiment, the layer of a luminescent polymeric material comprises a layer of MEH-PPV. The layer of second conductive material comprises a layer of metallic material that is configured to be a cathode component. In one embodiment, the layer of the second conductive material comprises a layer of aluminum, copper, silver, gold, alloy or the like. Alternatively, the layer of the second conductive material comprises a layer formed with a liquid-metal. In one embodiment, the liquid-metal is an indium-alloy liquid-metal. The layer of the second conductive material is deposited either by physical vapor deposition (thermal evaporation) or by RF plasma sputtering.

In use, when a voltage is applied between the layer of the first conductive material and the layer of the second conductive material, a light is emitted from the layer of the luminescent polymeric material of the PLED.

In a further aspect, the present invention relates to a PLED. In one embodiment, the PLED comprises a substrate, a layer of a first conductive material formed on a surface of the substrate, a layer of a luminescent polymeric material deposited on the layer of the conductive polymeric material, and a layer of a second conductive material formed on the layer of luminescent polymeric material, where the layer of a luminescent polymeric material is deposited by the LVD.

In yet a further aspect, the present invention relates to a backlight device formed with one or more PLEDs as set forth above, where the backlight device is configured for use in a display. Moreover, the present invention relates to an electronic or photonic or electro-optic device formed with one or more PLEDs as set forth above.

These and other aspects of the present invention will become apparent from the following description of the preferred embodiment taken in conjunction with the following drawings, although variations and modifications therein may be affected without departing from the spirit and scope of the novel concepts of the disclosure.

### BRIEF DESCRIPTION OF THE DRAWINGS

The patent or application file contains at least one drawing executed in color. Copies of this patent or patent application publication with color drawing(s) will be provided by the Patent and Trademark Office upon request and payment of the necessary fee.

The accompanying drawings illustrate one or more embodiments of the invention and, together with the written description, serve to explain the principles of the invention. Wherever possible, the same reference numbers are used throughout the drawings to refer to the same or like elements of an embodiment, and wherein:

FIG. 1 shows schematically an apparatus for forming a PLED according to one embodiment of the present invention;

FIG. 2 shows schematically a PLED according to one embodiment of the present invention;

FIG. 3 shows schematically a PLED according to another embodiment of the present invention;

FIG. 4 shows a PLED according to one embodiment of the present invention; and

FIG. 5 shows a PLED according to another embodiment of the present invention.

### DETAILED DESCRIPTION OF THE INVENTION

The present invention is more particularly described in the following examples that are intended as illustrative only since numerous modifications and variations therein will be apparent to those skilled in the art. Various embodiments of the invention are now described in detail. Referring to the drawings, like numbers indicate like parts throughout the views. As used in the description herein and throughout the claims that follow, the meaning of “a,” “an,” and “the” includes plural reference unless the context clearly dictates otherwise. Also, as used in the description herein and throughout the claims that follow, the meaning of “in” includes “in” and “on” unless the context clearly dictates otherwise. Additionally, certain theories are proposed and disclosed herein; however, in no way they, whether they are right or wrong, should limit the scope of the invention. Furthermore, titles or subtitles may be used in the specification for the convenience of a reader, which shall have no influence on the scope of the present invention.

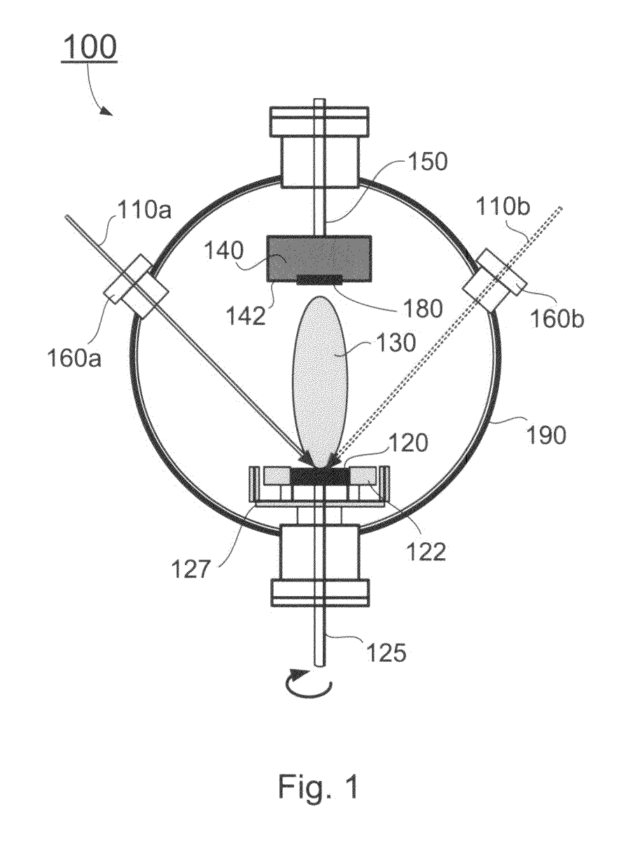

The description will be made as to the embodiments of the present invention in conjunction with the accompanying drawings of FIGS. 1-5. In accordance with the purposes of this invention, as embodied and broadly described herein, this invention, in one aspect, relates to a method of forming a multi-layer polymer organic light-emitting diode (polymer OLED or simply PLED) by resonant infrared laser vapor deposition (LVD). The present invention solves critical problems that confront the opto-electronic device industry, stemming from the fact that the present fabrication techniques require both vacuum- and liquid-phase deposition steps. This combination introduces significant complexity (and therefore cost) into OLED fabrication, as well as problems with contamination, solvent compatibility in multi-layer devices, and pixellation of large-area displays. Because LVD is a vacuum phase deposition technique, it is possible to employ essentially all of the usual techniques, such as shadow-masking, that are compatible with other vacuum-phase deposition methods, for example, sputtering, thermal evaporation or chemical-vapor deposition. Whereas these “conventional” vacuum-phase deposition techniques are limited to inorganic or small-molecule organic materials and often require heating of substrates to high-temperatures or post-deposition annealing steps, LVD is compatible with all polymers investigated to date, and is commonly done at low temperature, thus allowing the fabrication of PLEDs on plastic substrates.

More specifically, the method in one embodiment includes the following steps: at first, a solution having at least one polymeric material and one or more solvents is provided, where at least one solvent has a vibrational mode. The solution is frozen to form a target. The target is then introduced into a vacuum chamber, which is subsequently brought to a low pressure vacuum. A light of a wavelength in the infrared region which is resonant with the vibrational mode is directed at the target to vaporize the at least one polymeric material in the target without decomposing the at least one polymeric material. The vaporized at least one polymeric material is deposited on a substrate to form a layer of the polymeric material. Additionally, a cathode component is formed on the layer of the polymeric material so as to form a PLED.

The at least one polymeric material is semi-conductive or conductive. In one embodiment, the at least one polymeric material includes a luminescent polymeric material, such as MEH-PPV. The thickness of the layer of the semi-conductive or conductive polymeric material deposited on the substrate is in the range of about 10 Å to 500 microns.

The substrate is a transparent conducting substrate. In one embodiment, the substrate is an indium-tin oxide coated glass substrate, where a layer of the indium-tin oxide is deposited on a surface of a glass substrate. The substrate is configured to have an anode component.

The cathode component comprises a metallic or liquid-metal cathode. In one embodiment, the liquid-metal cathode is an indium-alloy liquid-metal cathode. The metal cathode can be an aluminum cathode, a copper cathode, a silver cathode, a gold cathode or the like.

When a voltage is applied between the anode component and the cathode component, holes are injected from the anode and electrons are injected from the cathode into the MEH-PPV layer. The recombination of the injected holes and electrons in the MEH-PPV layer results in light emission from the MEH-PPV layer.

In another embodiment, the at least one polymeric material includes a hole-transport polymeric material, such as PEDOT or PEDOT:PSS. The at least one polymeric material further includes a luminescent polymeric material, such as MEH-PPV. Accordingly, the step of depositing the vaporized at least one polymeric material on the substrate to form a layer of the polymeric material includes the steps of depositing the vaporized PEDOT or PEDOT:PSS on the indium-tin oxide coated glass substrate to form a layer of PEDOT or PEDOT:PSS; and depositing the vaporized luminescent polymeric material on the layer of PEDOT or PEDOT:PSS to form a layer of the luminescent polymeric material. The layer of PEDOT or PEDOT:PSS is adapted for promoting the hole injection into the layer of the luminescent polymeric material, thereby enhancing the recombination of the injected holes and electrons in the layer of the luminescent polymeric material results in light emission from the layer of the luminescent polymeric material. Accordingly, for a voltage bias applied between the anode and the cathode, the PLED having a layer of a hole-transport polymeric material emits light brighter than that emitted from the PLED without the layer of the hole-transport polymeric material.

In practice, the target and the substrate are placed in an environment selected from the group consisting of sub-atmospheric, atmospheric and above atmospheric pressure and located in the vicinity of each other so that the vaporized at least one polymeric material from the target is deposited on the substrate by a movement of the vaporized at least one polymeric material. The temperature of the substrate is adapted such that the vaporized at least one polymeric material deposited on the substrate becomes solid. The environment, in one embodiment, is sub-atmospheric pressure in the range of about 1×10⁻⁰ Torr to 1×10⁻⁶ Torr. The distance between the target and the substrate is in the range of about 1 to 20 cm.

Furthermore, the infrared laser emitting the light used to direct at the target is operating in cooperation with a rotatable holder supporting the substrate such that the laser delivers a laser spot that rastered on the surface of the target in synchronization with a rotation of the rotatable holder.

According to one embodiment of the present invention, the one or more solvents comprise a chemically stable solvent. The chemically stable solvent, in one embodiment, comprises water, where the light is resonant with a vibrational mode of water in liquid form or in solid form.

The one or more solvents may comprise an additional solvent that is at least partially soluble in the chemically stable solvent and has a vibrational mode that may be different from that of the chemically stable solvent. The additional solvent can be N-Methyl-2-pyrrolidinone or dichlorobenzene. The light is resonant with a vibrational mode of N-Methyl-2-pyrrolidinone, and the vibrational mode of N-Methyl-2-pyrrolidinone is about 3.45 microns.

The chemically stable solvent has a concentration in the range of about 5% to 95% by volume in the solution, the additional solvent has a concentration in the range of about 1% to 90% by volume in the solution, and the semi-conductive or conductive polymeric material is in the range of about 0.1% to 90% by weight in the solution.

In the present invention, among other things, the selection of a laser wavelength is critical to producing an even coating of material and in preserving the functionality of the at least one polymeric material. Attempts to transfer organic material with ultraviolet lasers have usually resulted in the degradation of the material due to photochemical modification. Infrared photons, being less energetic, couple instead into one or more vibrational modes of the target and at the energies used in this technique are insufficient to initiate electronic excitation. The use of infrared irradiation has the ability to transfer more material per laser shot, as the penetration depth of infrared photons is generally several orders of magnitude larger than that for ultraviolet photons for the materials of interest. Furthermore, within the infrared spectrum, there is some evidence in reports for transfer of polymeric material that selecting a mode resonant with a vibrational mode of the target is important for maintaining its physical and chemical properties. Additionally, the ablation dynamics are different at non-resonant wavelengths, and early results suggest that larger chunks are generated at non-resonant wavelengths, which can result in the transfer of chunks of materials to the substrate and thus uneven coatings.

According to one embodiment of the present invention, the light using to vaporize the target has a wavelength in the infrared region which is resonant with a vibrational absorption mode of the one or more solvents in a liquid form or a solid form. The vibrational mode of the one or more solvents, thus, the vibrational mode of the target is selectable from an absorption spectrum of the target, and is selected such that there is substantially no electronic excitation in the target caused by irradiating the target with the light. In one embodiment, the vibrational mode of the target is in the infrared region of about 0.1-10,000.0 μm. Accordingly, a layer of the at least one polymeric material can be grown in minutes instead of hours or days.

In other words, the appropriate wavelength of the light, corresponding to resonant vibrational excitation, can be determined by examining the infrared absorption spectrum of the target material that is to be transferred onto a substrate in solid form via laser evaporation. The infrared spectrum has characteristic absorption bands that are used to identify the chemical structure of the material. The resonant excitation wavelength of the target can be determined by identifying the wavelength associated with one of the absorption bands, and then using a light source, such as a tunable laser in the infrared region or a fixed frequency laser that is resonant with the vibrational absorption band, to generate such light having a wavelength resonant with the vibrational absorption mode of the target, which is directed at the target material. Light of more than one resonant wavelength can also be used to practice the present invention.

The light is delivered by a light source in the form of one or more pulses or in the form of continuous waves. The one or more pulses may have the pulse duration of about 100 fs to 5 ms at a pulse repetition frequency in the range of about 1 Hz to 3 GHz.

The light source for the LVD can be a tunable laser in the infrared region or a fixed frequency laser that is resonant with the vibrational absorption band of the target according to embodiments of the present invention. The suitable laser light source in one example is an FEL that is continuously tunable in the mid-infrared range of 2-10 μm or 5,000 to 1,000 cm⁻¹. The present invention can be practiced by using an FEL at Vanderbilt University in Nashville, Tenn. The Vanderbilt FEL laser produces an approximately 4 μs wide macropulse at a repetition rate of 30 Hz. The macropulse is made up of approximately 20,000 1-ps micropulses separated by 350 ps. The energy in each macropulse is on the order of 10 mJ so that the peak unfocused power in each micropulse is very high. The average power of the FEL laser is on the order of 2-3 W. For thin films deposited on a substrate by resonant infrared pulsed laser deposition, as described herein, the fluence is typically between 2 and 3 J/cm² and typical deposition rate is 100 ng/cm²/macropulse although it is in the range of 1 to 300 ng/cm²/pulse. The picosecond pulse structure of the FEL may play a unique and critical role in making possible RIR-LANT with low pulse energy but high intensity.

Fortunately, it appears that there may be a solution to this problem in the form of tunable, all-solid-state IR laser systems built from commercial components. Other laser sources, for example, a CO₂ laser, a tunable OPO laser system, an N₂ laser, an excimer laser, a Ho:YAG laser, or an Er:YAG laser, or the like, can also be employed to practice the current invention.

Another aspect of the present invention relates to a method for forming a multilayer PLED by the LVD process. The PLED fabrication involves preparing one or more different frozen targets, each containing a corresponding polymeric material of a layer (component) of the multilayer PLED, in a solution with one or more solvent components that are chosen to optimize the deposition process.

For example, for fabrication of a PLED having conductive and luminescent polymer layers, a first target and a second target are provided respectively in their frozen state. The first target includes a conductive polymeric material and one or more first solvents, at least one first solvent having a vibrational mode. The second target includes a luminescent polymeric material and one or more additional solvents, at least one additional solvent having a vibrational mode. The one or more first solvents and the one or more additional solvents are identical to or substantially different from each other. The conductive polymeric material can be a hole-transport polymeric material including, for example, PEDOT or PEDOT:PSS. The luminescent polymeric material is MEH-PPV.

These targets can be introduced one at a time into a vacuum chamber for deposition of the conductive polymeric material and the luminescent polymeric material. Alternatively, in the preferred realization of the PLED fabrication tool there would be one or multiple targets available within the vacuum chamber simultaneously.

Then, a first light is directed at the first target to vaporize the conductive polymeric material in the first target without decomposing the conductive polymeric material. The vaporized conductive polymeric material is deposited on a substrate to form a layer of the conductive polymeric material thereon. The substrate is a transparent conducting substrate having a glass substrate coated with a layer of an ITO configured to have an anode component.

Sequentially, a second light is directed at the second target to vaporize the luminescent polymeric material in the second target without decomposing the luminescent polymeric material. The vaporized luminescent polymeric material is deposited on the layer of the conductive polymeric material to form a layer of the luminescent polymeric material thereon.

The first light has a wavelength in the infrared region resonant with the vibrational mode of the first target. The second light has a wavelength in the infrared region resonant with the vibrational mode of the second target. The first light and the second light can be generated from a single infrared laser, or two different infrared lasers.

Next, a cathode component is formed on the layer of the luminescent polymeric material.

Accordingly, the PLED has four layers including the ITO layer (anode component), the hole-transport polymer layer, the luminescent polymer layer, and the cathode component. When a voltage is applied between the anode component and the cathode component, holes are injected from the anode, through the hole-transport polymer layer, into the luminescent polymer layer, and electrons are injected from the cathode into the luminescent polymer layer. The injected holes and electrons recombine therein, thereby emitting photons (light). The use of the hole-transport polymer layer enhances the hole injection.

Referring now to FIG. 1, an apparatus 100 for depositing a polymeric material onto a substrate by the LVD is shown according to one embodiment of the present invention. The polymeric material is mixed with one or more solvents to form a solution, which is then frozen to form a target 120 for the LVD. The apparatus 100 has an infrared laser source (not shown) capable of emitting an infrared laser beam 110a with a wavelength resonant with a vibrational mode of the one or more solvents in the frozen target 120. The infrared laser beam 110a tuned to the vibrational mode of the one or more solvents is directed at the frozen target 120 through a focusing means 160a to vaporize the frozen target 120 into a laser plume 130. The frozen target 120 is placed in a target well 122 received by a target carousel 127 that is engaged with a rotatable platform 125. The substrate 140 is positioned on a heatable sample stage 150 and has a surface 142 facing opposite to the target 120 such that the laser plume 130 of the vaporized polymeric material is capable of reaching the surface 142 of the substrate 140 by a movement away from the target well 122 and towards the substrate surface 142 which is caused by the vaporization and being deposited thereon. The temperature of the substrate 140 is adapted such that the vaporized polymeric material deposited on the substrate becomes solid, thereby forming a layer of the polymeric material thereon.

Alternatively, the polymeric material deposited on the surface 142 of the substrate 140 by means of the laser plume 130 can be also thermally cured to form a layer 180 of the polymeric material thereon. Curing can be done by the laser beam 110a, in which case the relative position and orientation of the sample stage 150 and the focus means 160a is adjustable so that the laser beam 110 is reachable to the deposited material on the substrate 140. Curing can also be done by an optional, second light source (not shown), in which case the second light source is positioned such that the light beam 110b from the second light source through a focus means 160b is reachable to the deposited material on the substrate 140. Curing can also be done by heating or by other means such as electrical current heating, in which case one or more electrical resistors are associated with the stage for heating the deposited material. The stage itself can be conductive to function as an electrical heater. The one or more resistors can be placed according to a predetermined pattern to selectively heat the target material deposited on the substrate. The light beam 110b from the optional second light source can be a laser or a broadband light source, which can be in resonant with a vibrational or electronic mode of other solvent(s) in the target to facilitate the vaporization and/or deposition process.

Additionally, the light beam 110b emitted from the second light source may also be employed to vaporize the polymeric material in the target 120. In the case, the wavelength of the light beam 110b is tuned to be resonant with the vibrational mode of the target 120.

For the PLED according to embodiments of the present invention, the substrate 140 is a transparent conducting substrate. For example, the substrate 140 can be an indium-tin oxide coated glass substrate, where a layer of the indium-tin oxide is deposited on a surface of a glass substrate. The substrate 140 is configured to have an anode component.

The substrate 140 can be of any solid material that can be vaporized by resonant infrared excitation, including organic, especially polymeric materials, inorganic materials, and biological materials. The substrate 140 can be any material that will accept the vapor as a deposited coating and can include planar or non-planar surfaces as well as particles.

In the embodiment shown in FIG. 1, the apparatus 100 operates in a vacuum chamber 190, where the atmospheric pressure can be adjusted in the range of about 1 Torr to 1×10⁻⁶ Torr.

Additionally, according to one embodiment of the present invention, the PLED fabrication involves preparing one or more different frozen targets, each containing a corresponding polymeric material of a layer (component) of the multilayer PLED, in a solution with one or more solvent components that are chosen to optimize the deposition process. Although these targets have been introduced one at a time into a vacuum chamber for the exemplary experiments, in the preferred realization of the PLED fabrication tool there would be one or multiple targets available within the chamber simultaneously.

The apparatus 100 shown in FIG. 1 can be used to deposit a layer of a polymeric material, or any other material that can be vaporized by application of infrared energy to the target material. The layer as formed is essentially chemically the same as the original target material without having undergone any essential chemical and/or structural modification.

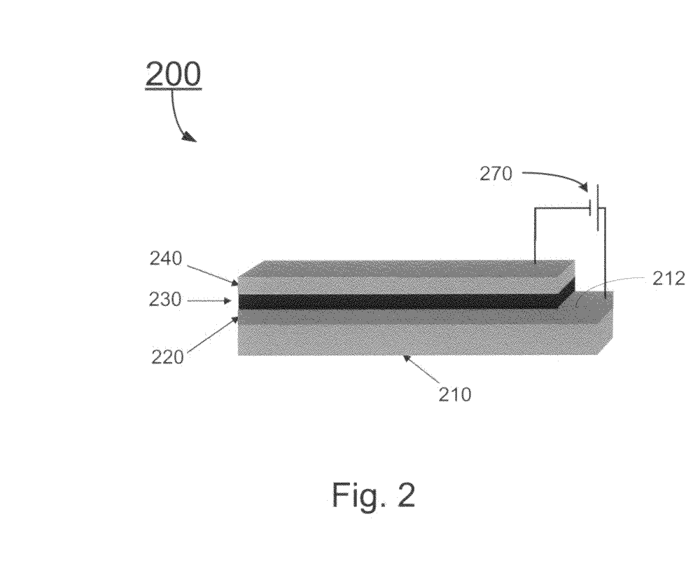

Referring to FIG. 2, a PLED 200 is schematically shown according to one embodiment of the present invention. The PLED 200 has a substrate 210, a layer 220 of a first conductive material formed on a surface 212 of the substrate 210, a layer 230 of a luminescent polymeric material deposited on the layer 220 of the first conductive material, and a layer 240 of a second conductive material formed on the layer of luminescent polymeric material. The layer 230 of the luminescent polymeric material is deposited by laser vapor deposition.

The substrate 210 and the layer 220 of the first conductive material are at least partially transparent. The layer 220 of the first conductive material and the layer 240 of the second conductive material are configured to have an anode component and a cathode component, respectively. The former is adapted for hole injection into the layer 230 of the luminescent polymeric material, while the latter is adapted for electron injection into the layer 230 of the luminescent polymeric material. The recombination of the injected holes and electrons in the layer 230 of the luminescent polymeric material results in light emission from the layer 230 of the luminescent polymeric material.

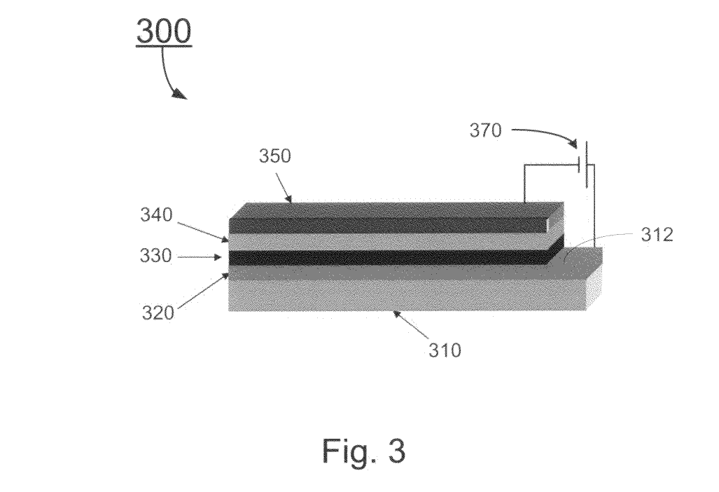

Referring to FIG. 3, a PLED 300 is schematically shown according to one embodiment of the present invention. The PLED has a substrate 310, a layer 320 of a first conductive material formed on a surface 312 of the substrate 310, a layer 330 of a conductive polymeric material deposited on the layer 320 of the first conductive material, a layer 340 of a luminescent polymeric material deposited on the layer 330 of the conductive polymeric material, and a layer 350 of a second conductive material formed on the layer 340 of the luminescent polymeric material. At least one of the layer 330 of the conductive polymeric material and the layer 340 of the luminescent polymeric material is deposited by the LVD process as set forth above.

The substrate 310 is at least partially transparent. In one embodiment, the transparent substrate is a glass substrate. The layer 320 of the first conductive material is a layer of at least partially transparent conducting oxide that is configured to be an anode component. In one embodiment, the layer of the at least partially transparent conducting oxide is a layer of ITO. The layer 330 of the conductive polymeric material comprises a layer of a hole-transport polymeric material. The hole-transport polymeric material can be PEDOT, PEDOT:PSS or the like. The layer 340 of the luminescent polymeric material is a semi-conductive polymeric material. In one embodiment, the layer 340 of the luminescent polymeric material comprises a layer of MEH-PPV. The layer 350 of the second conductive material comprises a layer of metallic material that is configured to be a cathode component. In one embodiment, the layer 350 of the second conductive material comprises a layer of aluminum, copper, silver, gold, alloy, or the like. Alternatively, the layer 350 of the second conductive material comprises a layer formed with a liquid-metal. In one embodiment, the liquid-metal is an indium-alloy liquid-metal. The layer 350 of the second conductive material is deposited either by physical vapor deposition (thermal evaporation) or by RF plasma sputtering.

In use, when a voltage is applied through a power source 370 between the layer 320 of the first conductive material and the layer 350 of the second conductive material, a light is emitted from the layer 340 of the luminescent polymeric material.

The layer 330 of the hole-transport polymeric material such as PEDOT or PEDOT:PSS is adapted for promoting the hole injection into the layer 340 of the luminescent polymeric material such as MEH-PPV. Accordingly, the light emitted from the PLED shown in FIG. 3 is brighter that that from the PLED shown in FIG. 2.

One aspect of the present invention relates to a backlight device formed with one or more PLEDs as set forth above, where the backlight device is configured for use in a display. Moreover, the present invention relates to an electronic or photonic or electro-optic device formed with one or more PLEDs as set forth above.

The present invention, among other things, discloses a novel technology that involves the fabrication of patterned light-emitting surfaces for displays. Although there have been techniques proposed for making pixellated light emitters using alternative fabrication methods such as ink jet printing, a dry, vacuum-phase beam deposition technique offers significant technical advantages in speed and cost-effectiveness in the manufacturing of PLED devices. The most likely uses of the invention are in the display industry, where the high brightness, ease of fabrication, and possibility of making light-emitting displays on heat-sensitive materials, such as plastics, could lead to early adoption of the technology. One of the advantages of this fabrication method is that it makes possible cost-effective, rapid prototyping of novel thin-film optoelectronic devices, as well as the previously cited possibilities for production technology.

Among other things, the present invention differs primarily and fundamentally from current technologies in the following aspects:

The use of an infrared laser instead of an ultraviolet laser for all steps in the fabrication of the multilayer PLED. The ultraviolet laser light excites electronic states in the irradiated material, where electronic excitation can result in unpredictable transformations of organic result in undesirable photochemical, photothermal or electronic degradation. However, tunable infrared laser irradiation couples to materials by selective vibrational excitation, thereby selecting or controlling the photochemical response of organic materials.

Additionally, infrared laser vaporization transfers substantially more material per laser shot compared to ultraviolet laser ablation, as the penetration depth of infrared photons is generally several orders of magnitude larger than that for ultraviolet photons for the materials of interest. The practical result of this is that usable layers can be grown in minutes instead of hours or days.

The use of multiple wavelengths, multiple target preparations, and multiple deposition protocols in the same vacuum chamber to build up a multi-layer structure with all the elements—charge-transport layers, luminescent layers, buffer and passivation layers—needed for a working PLED.

### Examples of the Invention

Without intent to limit the scope of the invention, additional exemplary methods and their related results according to the embodiments of the present invention are given below. Note that titles or subtitles may be used in the examples for convenience of a reader, which in no way should limit the scope of the invention. Moreover, certain theories are proposed and disclosed herein; however, in no way they, whether they are right or wrong, should limit the scope of the invention so long as data are processed, sampled, converted, or the like according to the invention without regard for any particular theory or scheme of action.

In the following two examples, a PLED was made by starting with a glass substrate that is already coated with a layer of ITO (a transparent conducting oxide), which is commercially available (although one can deposit an ITO layer on a glass substrate by an available deposition process). One purpose of the ITO is to inject “holes” into the light emitting layer of MEH-PPV. In one example, only the MEH-PPV layer was deposited on top of the ITO layer, while in the other example, the PEDOT layer was on the top of the ITO layer, and then the MEH-PPV layer was deposited the PEDOT layer by the LVD. The PLED could operate without the PEDOT layer, but its presence does give enhanced performance as it facilitates hole injection into the MEH-PPV layer. The MEH-PPV layer is the light emitting polymer and is semi-conducting with a direct bandgap that lies in the visible range and is “sandwiched” between the anodic and cathodic electrodes of the PLED. The aluminum is deposited either by physical vapor deposition (thermal evaporation) or by RF plasma sputtering. In use, a voltage bias between the ITO anode and the Aluminum cathode causes holes to be injected from the ITO anode and electrons to be injected from the Aluminum cathode into the MEH-PPV layer. The recombination of the injected holes and electrons in the MEH-PPV layer results in light emission from the MEH-PPV layer.

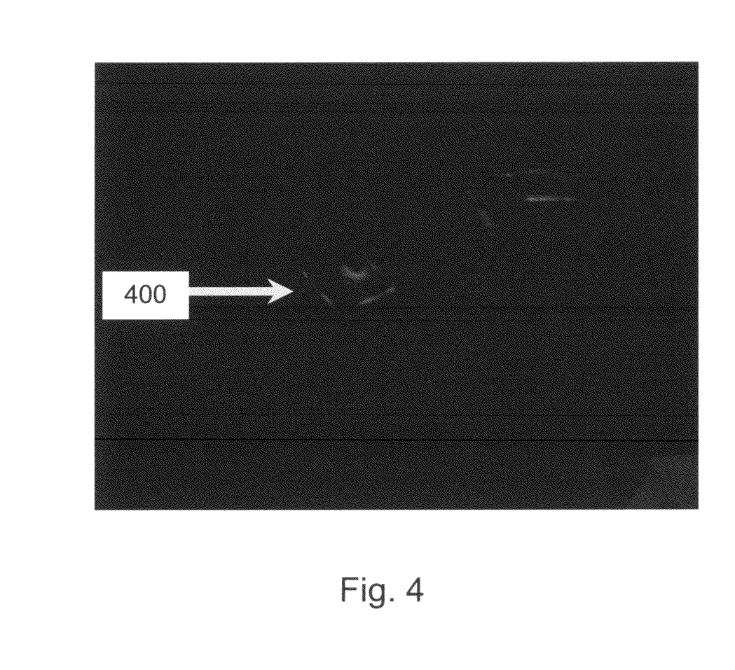

FIG. 4 shows a picture of a PLED 400 with light emission. The PLED 400 was made by depositing MEH-PPV, a polymer emitting light at the red end of the visible spectrum, onto a glass substrate coated with transparent conducting oxide such as ITO, following by application of a liquid-metal cathode on the top of the MEH-PPV layer. The layer of ITO coated on the glass substrate is configured to be an anode. The metal cathode is formed of a Gallium-Indium eutectic, which is a liquid at room temperature. Other metal cathode such as Aluminum cathode, gold cathode, sliver cathode, and so on, can also be utilized to practice the present invention. By applying a DC voltage of about 12 V between the anode and cathode, the light emission from the MEH-PPV layer is observed.

PEDOT:PSS is a novel, widely used material in the fabrication of polymer organic light emitting devices (PLEDs). Its high conductivity and near transparency in thin film form make it a perfect candidate for an anode or hole-transport layer (HTP) in a PLED. The inherent difficulty in its processing, however, has proven to be an obstacle to efficiently manufacturable and reliable devices. An all-vacuum process, which is desirable in the fabrication of any high performance electronic device, is not presently possible due to the current processing methods of PEDOT:PSS, which is usually deposited via a spin-coat technique. The following example clearly demonstrates that the fabrication process according to one embodiment of the present invention which does not require the exposure of the device to atmosphere during fabrication can be utilized for the fabrication of PEDOT:PSS based PLEDs.

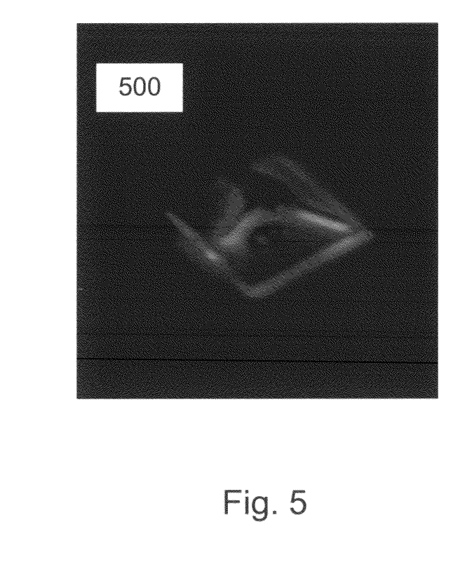

FIG. 5 shows a picture of a four-layer PLED 500 with light emission. The four-layer PLED 500 is fabricated as follows: at first, the hole-transport polymer, PEDOT:PSS (marketed by H. C. Stark Co. as Baytron-P), was deposited on an ITO coated glass cathode. Subsequently the luminescent polymer, MEH-PPV, dissolved in dichlorobenzene, was deposited from a frozen target on the top of the PEDOT:PSS layer. The final step in the fabrication of the PLED was the application of an indium alloy liquid-metal cathode on the top of the MEH-PPV layer. Upon the application of a DC voltage of approximately 12 V between the anode and cathode, light emission was observed. Compared to the PLED shown in FIG. 4, in which only the MEH-PPV luminescent polymer was deposited between the anode and cathode, both the brightness and the lifetime of the light emission increased, as would be expected from the properties of the hole transport material.

The present invention, among other things, discloses fabrication methods of a PLED device by a laser vaporization and thin-film deposition protocol for polymers. The first-ever demonstration of a vacuum-phase deposition technique, infrared laser vapor deposition, to fabricate a functioning PLED was disclosed. Laser-vaporized polymers were deposited on a transparent conducting substrate to produce a two or more layer structure, and capped with a metal cathode, which exhibited broadband electroluminescence. The previous attempts to observe electroluminescence by resonant infrared pulsed laser deposition polymer MEH-PPV [8] were unsuccessful; and only photoluminescence was observed, a much less stringent test of polymer light emitters than electroluminescence. The utility of the invention is clear: it demonstrates a realistic fabrication technique for making PLEDs at low process temperature and in vacuum, without the contamination and other problems associated with the liquid-phase spin-coating.

The advantages of the present invention over current technologies for forming PLEDs include, but are not limited to: (1) it makes it possible to move away from small organic light-emitters that must be deposited at high temperature; (2) selectivity in choosing the optimum vaporization wavelength makes for flexibility in the choice of the vaporization laser; (3) the LVD process obviates a separate liquid phase processing that involves expensive materials and complex waste-disposal streams; (4) the LVD process is extremely efficient in the use of expensive raw materials for PLEDs, thus reducing the cost of processing; (5) the process is applicable to many different polymers, thus enabling changes or substitutions of materials without expensive process development; and (6) this demonstration of a multilayer functional device shows the critical capability for the fabrication of entire electronic, photonic or electro-optic devices—such as PLED displays or thin-film transistors—in vacuum, eliminating a major source of contamination in the manufacture of organic devices and ultimately enhancing product yield.

The foregoing description of the exemplary embodiments of the invention has been presented only for the purposes of illustration and description and is not intended to be exhaustive or to limit the invention to the precise forms disclosed. Many modifications and variations are possible in light of the above teaching.

The embodiments were chosen and described in order to explain the principles of the invention and their practical application so as to enable others skilled in the art to utilize the invention and various embodiments and with various modifications as are suited to the particular use contemplated. Alternative embodiments will become apparent to those skilled in the art to which the present invention pertains without departing from its spirit and scope. Accordingly, the scope of the present invention is defined by the appended claims rather than the foregoing description and the exemplary embodiments described therein.

### LIST OF REFERENCES

[1]. “Pulsed Laser Deposition of Polymer Films Using a Resonantly Tunable Infrared Laser,” D. M. Bubb, J. H. Callahan, J. S. Horwitz, R. A. McGill, E. J. Houser, D. B. Chrisey, M. R. Papantonakis, R. F. Haglund, Jr., M. Galicia and A. Vertes, J. Vac. Sci. Tech. A 19, 2698-2702 (2001). Rapid Communication.
[2]. “Resonant Infrared Pulsed Laser Deposition of a Sorbent Chemoselective Polymer,” D. M. Bubb, D. B. Chrisey, M. R. Papantonakis, R. F. Haglund, Jr., J. S. Horwitz, R. A. McGill and B. Toftmann, Appl. Phys. Lett. 79, 2847-2849 (2001).
[3]. “Deposition of thin biodegradable polymer films by resonant infrared pulsed laser deposition,” D. M. Bubb, B. Toftmann, R. F. Haglund, Jr., Jr., J. S. Horwitz, M. R. Papantonakis, R. A. McGill, P. W. Wu, and D. B. Chrisey, Applied Physics A 121, 123-125 (2002).
[4]. “Vapor Deposition of Polystyrene Thin Films by Intense Laser Excitation of Resonant Vibrational Modes,” D. M. Bubb, M. R. Papantonakis, R. F. Haglund, Jr., J. S. Horwitz, R. A. McGill and D. B. Chrisey, Chemical Physics Letters 352, 135-139 (2002).
[5]. “Effect of ablation parameters on infrared pulsed laser deposition of poly(ethylene glycol) thin films,” D. M. Bubb, M. R. Papantonakis, B. Toftmann, J. S. Horwitz, E. J. Houser, D.
[6]. B. Chrisey and R. F. Haglund, Jr., Journal of Applied Physics 91, 9809-9814 (2002).
[7]. “Laser deposition of polymer and biomaterial films”, D. B. Chrisey, A. Piqué, R. A. McGill, J. S. Horwitz, B. R. Ringeisen. D. M. Bubb and P. K. Wu, Chemical Reviews, 103, 553-576 (2003).
[8]. “UV and RIR matrix-assisted pulsed laser deposition of MEH-PPV films,” B. Toftmann, M. R. Papantonakis, R. C. Y. Auyeung, W. Kim, S. M. O'Malley, D. M. Bubb, J. S. Horwitz, J. Schou, P. M. Johansen and R. F. Haglund, Jr., Thin Solid Films 453-454, 177-181 (2004).
[9]. “Pulsed Laser Deposition of Polymers at High Vibrational Excitation Density: the Case of Poly(tetrafluoroethylene),” M. R. Papantonakis and R. F. Haglund, Jr., Applied Physics A: Materials and Processing 79, 1687-1694 (2004).
[10]. “Applications of Free-Electron Lasers in the Biological and Materials Sciences,” G. S. Edwards, S. J. Allen, R. F. Haglund, Jr., R. J. Nemanich, B. Redlich, J. D. Simon and W. C. Yang, Photochemistry and Photobiology 81, 711-735 (2005). Invited review.
[11]. “Mode-specific effects in resonant ablation and deposition of polystyrene,” D. M. Bubb, S. L. Johnson, Jr., R. J. Belmont, K. E. Schriver, R. F. Haglund, Jr., C. Antonacci and L. S. Yeung, Applied Physics A: Materials and Processing 83, 147-151 (2006).
[12]. “Resonant infrared pulsed laser deposition of a polyimide precursor,” N. L. Dygert, K. E. Schriver and R. F. Haglund, Jr., in press, Institute of Physics Conference Series, proceedings of the Eighth International Conference on Laser Ablation (2005).
[13]. “Vacuum deposition of PEDOT:PSS films by resonant infrared laser vaporization,” S. L. Johnson, H. K. Park and R. F. Haglund, Jr., submitted to Synthetic Metals, July 2006.
[14]. “Organic electroluminescence cells based on thin films deposited by ultraviolet laser ablation,” N. Matsumoto, H. Shima, T. Fujii, and F. Kannari, Applied Physics Letters 71 2469-2471 (1997).
[15]. “Pulsed-laser deposition for organic electroluminescent device applications,” S. R. Farrar, A. E. A. Contoret, M. O'Neill, and J. E. Nicholls, Applied Physics Letters 76 2553-2555 (2000).
[16]. “Characterization of pulsed-laser-deposited organic electroluminescent compounds for organic light-emitting diodes,” S. R. Farrar, A. E. A. Contoret, M. O'Neill, J. E. Nicholls, A. J. Eastwood, and S. M. Kelly, Synthetic Metals 121 1657-1658 (2001).
[17]. “The possibility of pulsed laser deposited organic thin films for light-emitting diodes,” C. Hong, H. B. Chae, K. H. Lee, S. K. Ahn, C. K. Kim, T. W. Kim, N. I. Cho, and S. O. Kim, Thin Solid Films 409, 37-42 (2002).
[18]. “Pulsed laser deposition of small molecules for organic electroluminescence,” S. R. Farrar, A. E. A. Contored, M. O'Neill, J. E. Nicholls, A. J. Eastwood, G. J. Richards, P. Vlachos, and S. M. Kelly, Applied Surface Science 186 435-440 (2002).

What is claimed is:

1. A method for forming a polymeric light-emitting diode (PLED), comprising the steps of:
a. providing a solution having at least one polymeric material and one or more solvents, wherein at least one solvent has a vibrational mode;
b. freezing the solution to form a target;
c. directing a light of a wavelength in the infrared region which is resonant with the vibrational mode of the at least one solvent at the target to vaporize the at least one polymeric material in the target without decomposing the at least one polymeric material;
d. depositing the vaporized at least one polymeric material on a substrate to form a layer of the at least one polymeric material; and
e. forming a cathode component on the layer of the at least one polymeric material so as to form a PLED.

2. The method of claim 1, wherein the at least one polymeric material comprises a luminescent polymeric material, and wherein the luminescent polymeric material comprises MEH-PPV.

3. The method of claim 1, wherein the at least one polymeric material comprises a hole-transport conductive polymeric material, and wherein the hole-transport conductive polymeric material is Poly(3,4-ethylenedioxythiophene) (“PEDOT”) or Poly(3,4-ethylenedioxythiophene)-poly(styrenesulfonate) (“PEDOT:PSS”).

4. The method of claim 3, wherein the at least one polymeric material further comprises a luminescent polymeric material, and wherein the depositing step comprises the steps of depositing the vaporized PEDOT or PEDOT:PSS on the substrate to form a layer of PEDOT or PEDOT:PSS; and depositing the vaporized luminescent polymeric material on the layer of PEDOT or PEDOT:PSS to form a layer of the luminescent polymeric material.

5. The method of claim 1, wherein the one or more solvents comprise a chemically stable solvent, and wherein the chemically stable solvent is water.

6. The method of claim 5, wherein the one or more solvents further comprises a solvent that is at least partially soluble in the chemically stable solvent and has a vibrational mode that is identical to or different from that of the chemically stable solvent, and wherein the solvent is dichlorobenzene or N-Methyl-2-pyrrolidinone.

7. The method of claim 1, wherein the light is generated from an infrared laser in the form of pulses or continuous wave with a flurency in a range of about 0.01 to 100 J/cm².

8. The method of claim 1, wherein the cathode component comprises a metal or liquid-metal cathode, and wherein the liquid-metal cathode is an indium-alloy liquid-metal cathode.

9. The method of claim 1, wherein the substrate is a transparent conducting substrate having a glass substrate coated with a layer of an indium-tin oxide (ITO) configured to have an anode component, and wherein when a voltage is applied between the anode component and the cathode component, a light is emitted from the PLED.

10. The method of claim 1, further comprising the steps of subjecting the target and the substrate to an environment selected from the group consisting of sub-atmospheric, atmospheric and above atmospheric pressure and locating the target and the substrate in the vicinity of each other so that the vaporized at least one polymeric material from the target is deposited on the substrate by a movement of the vaporized at least one polymeric material, wherein the temperature of the substrate is such that the vaporized at least one polymeric material deposited on the substrate becomes solid.

11. The method of claim 10, wherein the environment is sub-atmospheric pressure and wherein the sub-atmospheric pressure is in the range of about 1×11⁻⁰ Torr to 1×10⁻⁶ Torr.

12. A method for forming a polymeric light-emitting diode (PLED), comprising the steps of:
a. providing a first target in a frozen state and a second target in a frozen state, wherein the first target includes a conductive polymeric material and one or more first solvents, at least one first solvent having a vibrational mode, wherein the second target includes a luminescent polymeric material and one or more additional solvents, at least one additional solvent having a vibrational mode, and wherein the one or more additional solvents are identical to or substantially different from the one or more first solvents;
b. directing a first light at the first target to vaporize the conductive polymeric material in the first target without decomposing the conductive polymeric material, wherein the first light has a wavelength in the infrared region which is resonant with the vibrational mode of the first target;
c. depositing the vaporized conductive polymeric material on a substrate to form a layer of the conductive polymeric material;
d. repeating steps (b) and (c) for the second target to form a layer of the luminescent polymeric material on the layer of the conductive polymeric material, wherein a second light directing at the second target has a wavelength in the infrared region which is resonant with the vibrational mode of the second target so as to vaporize the luminescent polymeric material in the second target without decomposing the luminescent polymeric material; and
e. forming a cathode component on the layer of the luminescent polymeric material so as to form a PLED.

13. The method of claim 12, wherein the conductive polymeric material comprises a hole-transport polymeric material, and wherein the hole-transport polymeric material is Poly(3,4-ethylenedioxythiophene) (PEDOT) or Poly(3,4-ethylenedioxythiophene)-poly(styrenesulfonate) (PEDOT:PSS).

14. The method of claim 12, wherein the luminescent polymeric material comprises MEH-PPV.

15. The method of claim 12, wherein each of the one or more first solvents and the one or more additional solvents comprises a chemically stable solvent having a vibrational mode.

16. The method of claim 12, wherein the substrate is a transparent conducting substrate having a glass substrate coated with a layer of an indium-tin oxide (ITO) configured to have an anode component, and wherein when a voltage is applied between the anode component and the cathode component, a light is emitted from the PLED.

17. The method of claim 12, wherein the first light and the second light are generated from a single light source or two different light sources.

18. A polymeric light-emitting diode (PLED), comprising:
a. a substrate;
b. a layer of a first conductive material formed on a surface of the substrate;
c. a layer of a conductive polymeric material deposited on the layer of the first conductive material;
d. a layer of a luminescent polymeric material deposited on the layer of the conductive polymeric material; and
e. a layer of a second conductive material formed on the layer of luminescent polymeric material,
wherein at least one of the layer of the conductive polymeric material and the layer of the luminescent polymeric material is deposited by laser vapor deposition (LVD); and
wherein when a voltage is applied between the layer of a first conductive material and the layer of a second conductive material, a light is emitted from the layer of the luminescent polymeric material.

19. The PLED of claim 18, wherein the layer of the conductive polymeric material comprises a layer of the hole-transport polymeric material, and wherein the hole-transport polymeric material is Poly(3,4-ethylenedioxythiophene) (“PEDOT”) or Poly(3,4-ethylenedioxythiophene)-poly(styrenesulfonate) (“PEDOT:PSS”).

20. The PLED of claim 18, wherein the layer of the luminescent polymeric material comprises a semi-conductive polymeric material, and wherein the layer of the luminescent polymeric material comprises a layer of MEH-PPV.

21. The PLED of claim 18, wherein the layer of the first conductive material is a layer of at least partially transparent conducting oxide that is configured to be an anode component, and wherein the layer of the second conductive material comprises a layer of metallic material that is configured to be a cathode component.

22. The PLED of claim 21, wherein the layer of the second conductive material comprises a layer formed with a liquid-metal, and wherein the liquid-metal is an indium-alloy liquid-metal.

23. A polymeric light-emitting diode (PLED), comprising:
a. a substrate;
b. a layer of a first conductive material formed on a surface of the substrate;
c. a layer of a luminescent polymeric material deposited on the layer of the conductive polymeric material; and
d. a layer of a second conductive material formed on the layer of luminescent polymeric material,
wherein the layer of a luminescent polymeric material is deposited by laser vapor deposition; and
wherein when a voltage is applied between the layer of a first conductive material and the layer of a second conductive material, a light is emitted from the layer of the luminescent polymeric material.

24. The PLED of claim 23, wherein the layer of the luminescent polymeric material comprises a semi-conductive polymeric material, and wherein the layer of luminescent polymeric material comprises a layer of MEH-PPV.

25. The PLED of claim 23, wherein the layer of the first conductive material is a layer of at least partially transparent conducting oxide that is configured to be an anode component, and wherein the layer of the second conductive material comprises a layer of metallic material that is configured to be a cathode component.
